(19) United States
(12) Patent Application Publication
(10) Pub. No.: US 2002/0096747 A1
(43) Pub. Date: Jul. 25, 2002

(54) Package structure of an integrated circuit

(76) Inventors: Nai Hua Yeh, Hsinchu Hsien (TW); Kuang Yu Fan, Hsinchu Hsien (TW); Mon Nan Ho, Hsinchu Hsien (TW); C. S. Cheng, Hsinchu Hsien (TW); C. H. Chen, Hsinchu Hsien (TW); Fu Yung Huang, Hsinchu Hsien (TW); Yung Sheng Chiu, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/770,085

(22) Filed: Jan. 24, 2001

(51) Int. Cl. H01L 23/495; H01L 23/48; H01L 23/52; H01L 29/40

(52) U.S. Cl. 257/668; 257/784

(57) ABSTRACT

A package structure of an integrated circuit is used for electrically connecting to a printed circuit board includes a substrate, an integrated circuit, a plurality of wires, two molded resins. The substrate has a lower surface formed with signal input terminals and signal output terminals, which are to be connected to the signal input terminals. The signal output terminals are electrically connected to the printed circuit board. The integrated circuit has a lower surface for mounting the integrated circuit to the upper surface of the substrate. The two sides on the lower surface of the integrated circuit formed with a plurality of bonding pads. While the integrated circuit mounted to the substrate, the bonding pads are exposed to the outside. The plurality of wires are electrically connected the bonding pads to the substrate. Thus, the signals from the integrated circuit can be transmitted to the substrate. Two molded resins are filled into the two sides of the integrated circuit and the substrate for sealing the plurality of wires to prevent the wires. Thus, the integrated circuit can be made thin, small, and slight.

### BACKGROUND OF THE INVENTION

1. Field of the Invention

The present invention relates to a package structure of an integrated circuit, in particular, to a chip scale package in which can be made thin, small, and light.

As shown in FIG. 1 is a conventional package structure of an integrated circuit includes a substrate 10 has an upper surface 12 with signal input terminals 16 and has a lower surface 14 with signal output terminals 18, which are used for electrically connecting to printed circuit board 19. An integrated circuit 20 is mounted to the upper surface 12 of the substrate 10,and is formed with a plurality of bonding pads 22. A plurality of wires 24 is electrically connected the corresponding to bonding pads 22 to signal input terminals 16. A molded resin 26 is covered over the integrated circuit 20 and substrate 10 to prevent the integrated circuit 20 and the plurality of wires 24.

In accordance with above-described, the size of the substrate 10 have to larger than the integrated circuit 20, so as to the plurality of wires 24 are capable of electrically connecting to substrate 10. Thus, the size of package body is large, that can not be made thin, small, and slight.

In order to make the size of the package body into thin, small, and slight. An integrated circuit is electrically connected to the substrate by way of flip chip type. But, the processing costs are very high.

In order to solve the above-mentioned problems, the present invention provides a package structure of an integrated circuit to overcome the disadvantages caused by the conventional integrated circuit and the flip chip type.

### SUMMAYR OF THE PRESENT INVENTION

It is therefore an object of the present invention to provide a package structure of an integrated circuit for reducing the size of the package structure, so that the product can be made thin, small, and slight.

It is therefore another object of the present invention to provide a package structure of an integrated circuit to facilitate the manufacturing process and lower the manufacture costs.

According to one aspect of the present invention, a package structure of an integrated circuit is used for electrically connecting to a printed circuit board comprises a substrate, an integrated circuit, a plurality of wires, two molded resins. The substrate has a upper surface and a lower surface opposite to the upper surface, the lower surface being formed with signal input terminals and signal output terminals, which are to be connected to the signal input terminals. Then, the signal output terminals being electrically connected to the printed circuit board. The integrated circuit has a lower surface for mounting the integrated circuit to the upper surface of the substrate. The two sides on the lower surface of the integrated circuit formed with a plurality of bonding pads. While the integrated circuit mounted to the substrate, the bonding pads are exposed to the outside. The plurality of wires has a first end and a second end. Each of the first ends being electrically connected to the bonding pads of the integrated circuit and each of the second ends being electrically connected to the signal input terminals formed on the lower surface of the substrate. Thus, the signals from the integrated circuit can be transmitted to the substrate. Two molded resins are filled into the two sides of the integrated circuit and the substrate for sealing the plurality of wires to prevent the wires.

Thus, the integrated circuit can be made thin, small, and slight.

### BRIEF DESCRIPTION OF THE DRAWINGS

FIG. 1 is a schematic illustration showing a conventional package structure of an integrated circuit.

FIG. 2 is a cross-sectional view showing a package structure of an integrated circuit according to the present invention.

FIG. 3 is a cross-sectional view showing a package structure of an integrated circuit according to a second embodiment of the present invention.

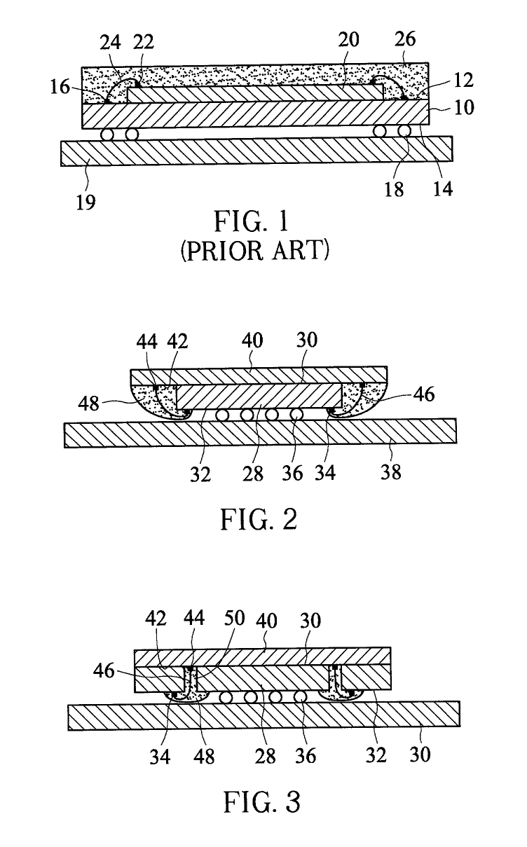

### DETAIL DESCRIPTION OF THE PRESENT INVENTION

The embodiment of the present invention will now be described reference to the drowning.

As shown in FIG. 2 is a package structure of an integrated circuit of the present invention includes a substrate 10, an integrated circuit 40, a plurality of wires 46 and two molded resins 48.

The substrate 28 has an upper surface 30 and a lower surface 32. The two sides of the lower surface 32 are formed with signal input terminals 34 and output terminals 36, which are electrically connected to the signal input terminals 32. The signal output terminals 36 are metallic balls arranged in the form of ball grid array, which are electrically connected to the printed circuit board 38. A signals from the substrate can be transmitted the printed circuit board.

The integrated circuit 40 has a lower surface 42 for mounting the integrated circuit 40 to the upper surface 30 of the substrate 28. A plurality of bonding pads 44 are formed on the two sides of the lower surface 42, Therefor, while integrated circuit 40 arranged on the upper surface 30 of the substrate 28, the plurality of bonding pads 44 are exposed to the outside. The embodiment of the present invention, the integrated circuit 40 is smaller than the substrate 28, thus, the plurality of bonding pads 44 on the integrated circuit 40 can not be covered by the substrate 28, therefore, the plurality of bonding pads 44 are exposed to outside.

The plurality of wires 46 has a first end and a second. Each of the first ends are electrically connected to the bonding pads 44 of the integrated circuit 40 and each of the second ends are electrically connected to the signal input terminals 34 formed on the lower surface 32 of the substrate 28, by way of wire bonding. Thus, the signals from the integrated circuit 40 can be transmitted to the substrate 28.

The two molded resins 48 are filled into the two sides of the integrated circuit 40 and the substrate 28, for preventing the plurality of wires 46.

Therefore, the embodiment of the present invention packages an integrated circuit with bonding pads and a substrate 28, which is smaller than the integrated circuit in size. Therefor, the package body is a chip scale package (CSP) type. Thus, the present invention is capable of lowering manufacturing costs.

Referring to FIG. 3 is showing a package structure of an integrated circuit according to a second embodiment of the present invention. The substrate 28 has an upper surface 30 and a lower surface 32. The two sides of the lower surface 32 is formed with signal input terminals 34 and signal output terminals 36, which are electrically connected to the signal input terminals 34. The signal output terminals 36 are metallic balls arranged in the form of ball grid array for electrically connecting to the print circuit board 38. Signals from the substrate 28 that are to be transmitted to the printed circuit board 38.

The two sides of the substrate 28 are formed with a slot 50, which is through into the substrate 28. While the integrated circuit 40 is adhered to the upper surface 30 of the substrate 28 by the lower surface 42, the bonding pads 44 formed on the integrated circuit 40 is exposed to outside through the slots 50 formed on the substrate 28.

The plurality of wires 46 are located within the slot 50 and are electrically connected the bonding pads 44 to the signal input terminals 34. The molded resin 48 is filled into the slots 50 to prevent the plurality of wires 46.

According to the above-mention structure, the following advantages can be obtained.

1. The quantity of the substrate can be reduced, thereby lowering the manufacturing costs.

2. The size of the integrated circuit 40 and the substrate 28 are similar in size, so as to the package body can be made thin, small, and light.

3. The processing of the package can be facilitated, and the manufacturing costs can also be reduced.

While the present invention has been described by way of example and in terms of preferred embodiments, it is to be understood that the present invention is not limited to the disclosed embodiments. Therefore, the scope of the appended claims should be accorded the broadest interpretation so as to encompass all such modifications.

What is claimed is:

1. A package structure of an integrated circuit is used for electrically connecting to the printed circuit board, comprising:
a substrate having a upper surface and a lower surface opposite to the upper surface, the lower surface being formed with signal input terminals and signal output terminals, which are to be connected to the signal input terminals. Then, the signal output terminals being electrically connected to the printed circuit board.
an integrated circuit having a lower surface for mounting the integrated circuit to the upper surface of the substrate. The two sides on the lower surface of the integrated circuit formed with a plurality of bonding pads. While the integrated circuit mounted to the substrate, the bonding pads are exposed to the outside.
a plurality of wires having a first end and a second end. Each of the first ends being electrically connected to the bonding pads of the integrated circuit and each of the second ends being electrically connected to the signal input terminals formed on the lower surface of the substrate. Thus, the signals from the integrated circuit can be transmitted to the substrate.
two molded resins are filled into the two sides of the integrated circuit and the substrate for sealing the plurality of wires to prevent the wires.

2. The package structure of an integrated circuit according to claim 1, wherein the size of the substrate is smaller than the integrated circuit, so that while the integrated circuit mounted to the substrate, the bonding pads formed on the integrated circuit is exposed to outside.

3. The stacked package structure of an image sensor according to claim 1, wherein the two sides of the substrate corresponding to the bonding pads of the integrated circuit is formed with a slot. So that, while integrated circuit is mounted to the substrate, the bonding pads are exposed to outside via the slot of the substrate.

4. The package structure of an integrated circuit according to claim 1, wherein the lower surface of the integrated is adhered on the upper surface of the substrate.

5. The package structure of an integrated circuit according to claim 1, wherein the signal output terminals of the substrate are metallic balls arranged in the form of the ball grid array.

6. The package structure of an integrated circuit according to claim 5, wherein the signal input terminals formed on the substrate is located on the two sides of the substrate.
